(19) United States
(12) Patent Application Publication
(10) Pub. No.: US 2025/0120104 A1
(43) Pub. Date: Apr. 10, 2025

(54) THIN FILM CAPACITOR, MANUFACTURING METHOD THEREFOR, AND ELECTRONIC CIRCUIT BOARD HAVING THE THIN FILM CAPACITOR

(71) Applicant: TDK Corporation, Tokyo (JP)

(72) Inventors: Yasunori HARADA, Tokyo (JP); Yoshiaki HAYAMIZU, Tokyo (JP); Daiki ISHII, Tokyo (JP); Mitsuhiro TOMIKAWA, Tokyo (JP); Kenichi YOSHIDA, Tokyo (JP)

(21) Appl. No.: 18/836,446

(22) PCT Filed: Dec. 2, 2022
(86) PCT No.: PCT/JP2022/044514

§ 371 Date: Aug. 7, 2024

Related U.S. Application Data
(60) Provisional application No. 63/310,707, filed on Feb. 16, 2022.

(51) Int. Cl. H10D 1/68

(52) U.S. Cl. CPC H10D 1/712

(57) ABSTRACT

To provide a thin film capacitor having a pair of terminal electrodes capable of being disposed on the same plane. A thin film capacitor 1 includes a metal foil having a non-roughened center portion and a roughened upper surface, a dielectric film covering the roughened upper surface of the metal foil, an electrode layer contacting the non-roughened center portion of the metal foil through an opening formed in the dielectric film, and an electrode layer contacting the dielectric film without contacting the metal foil. A thickness of the center portion of the metal foil at a position overlapping the electrode layer is larger than a thickness thereof at a position overlapping the electrode layer.

### TECHNICAL FIELD

The present disclosure relates to a thin film capacitor and a manufacturing method therefor, and an electronic circuit board having the thin film capacitor.

### BACKGROUND ART

IC-mounted circuit boards are commonly mounted with a decoupling capacitor so as to stabilize the potential of a power supply for an IC. As the decoupling capacitor, a multilayer ceramic chip capacitor is typically used, and a large number of the multilayer ceramic chip capacitors are mounted on the surface of the circuit board to thereby achieve a required decoupling capacitance.

In recent years, a mounting space for a large number of multilayer ceramic chip capacitors may become insufficient due to miniaturization of a circuit board. To cope with this, a thin film capacitor capable of being embedded in a circuit board is sometimes used in place of the multilayer ceramic chip capacitor (see Patent Documents 1 to 4).

A thin film capacitor described in Patent Document 1 uses a porous metal substrate and is structured such that an upper electrode is formed on the surface of the porous metal substrate with a dielectric film interposed therebetween. A thin-film capacitor described in Patent Document 2 uses a metal substrate whose one main surface is roughened and is structured such that an upper electrode is formed on the roughened surface with a dielectric film interposed therebetween. Thin film capacitors described in Patent Documents 3 and 4 are structured such that a conductive porous substrate is formed as a support, and an upper electrode is formed on a roughened surface of the substrate with a dielectric film interposed therebetween.

### CITATION LIST

### Patent Document

[Patent Document 1] International Publication WO 2015/118901
[Patent Document 2] International Publication WO 2018/092722
[Patent Document 3] International Publication WO 2017/026247
[Patent Document 4] International Publication WO 2017/014020

### DISCLOSURE OF THE INVENTION

### Problem to be Solved by the Invention

However, the thin film capacitor described in Patent Document 1 has a side surface electrode structure, so that the line length of the electrode is long, which causes a structural problem of increasing an ESR (Equivalent Series Resistance and an ESL (Equivalent Series Inductance). In addition, the thin film capacitor described in Patent Document 1 uses a metal substrate which is made entirely porous, so that it is not easy to separate a lower electrode constituted by the metal substrate and the upper electrode covering the metal substrate through the dielectric film, which disadvantageously makes it likely to cause a short circuit failure. In the thin film capacitor described in Patent Document 2, one main surface of the metal substrate functions as the upper electrode, and the other surface thereof functions as a lower electrode, so that, in order to dispose a pair of terminal electrodes on the same plane, it is necessary to route the electrode through the side surface of an element, complicating the structure. In the thin film capacitors described in Patent Documents 3 and 4, a pair of terminal electrodes are disposed on both surfaces of a metal substrate, respectively, preventing access to the terminal electrode pair from one side. In addition, the presence of the support increases the entire thickness.

The present disclosure describes an improved thin film capacitor and a manufacturing method therefor, and an electronic circuit board having such a thin film capacitor.

### Means for Solving the Problem

A thin film capacitor according to one aspect of the present disclosure includes a metal foil having a non-roughened center portion and a roughened surface, a dielectric film covering the roughened surface of the metal foil, a first electrode layer contacting the non-roughened center portion of the metal foil through an opening formed in the dielectric film, and a second electrode layer contacting the dielectric film without contacting the metal foil, wherein the center portion of the metal foil is larger in thickness at a position overlapping the first electrode layer than at a position overlapping the second electrode layer.

An electronic circuit board according to one aspect of the present disclosure includes a substrate having a wiring pattern, and a semiconductor IC and the thin film capacitor each provided in the substrate, wherein the first and second electrode layers of the thin film capacitor are connected to the semiconductor IC through the wiring pattern.

A method of manufacturing a thin film capacitor according to one aspect of the present disclosure includes partially roughening a surface of a metal foil to form, on the metal foil surface, a first region where a non-roughened center portion is exposed and a roughened second region; forming a dielectric film on the second region of the metal foil surface; and forming a first electrode layer contacting the first region of the metal foil surface and a second electrode layer contacting the dielectric film without contacting the metal foil.

### Advantageous Effect of the Invention

According to the present disclosure, the dielectric film has an opening, which allows a pair of terminal electrodes to be disposed on the same plane without using a side surface electrode. In addition, the center portion of the metal foil has a large thickness at a position overlapping the first electrode layer, so that the metal foil is hardly ruptured due to stress applied through the first electrode layer.

### BRIEF DESCRIPTION OF THE DRAWINGS

FIG. 1A is a schematic cross-sectional view for explaining the structure of a thin film capacitor 1 according to a first embodiment of the present disclosure.

FIG. 1B is a schematic plan view of the thin film capacitor 1.

FIGS. 2A to 25A are schematic cross-sectional views for explaining a manufacturing process of the thin film capacitor 1 and taken along the line A-A in FIGS. 2B to 25B.

FIG. 26 is a schematic cross-sectional view for explaining the structure of a thin film capacitor 2 according to a second embodiment of the present disclosure.

FIG. 27 is a schematic cross-sectional view for explaining the structure of a thin film capacitor according to a third embodiment of the present disclosure.

FIG. 28 is a schematic cross-sectional view for explaining the structure of a thin film capacitor 4 according to a fourth embodiment of the present disclosure.

FIG. 29 is a schematic cross-sectional view showing an electronic circuit board having a configuration in which any one of the thin film capacitors 1 to 4 is embedded in a multilayer substrate 400.

FIG. 30 is a schematic cross-sectional view showing an electronic circuit board having a configuration in which any one of the thin film capacitors 1 to 4 is mounted on a multilayer substrate 600.

### MODE FOR CARRYING OUT THE INVENTION

Hereinafter, some embodiments of the present disclosure will be described in detail with reference to the accompanying drawings.

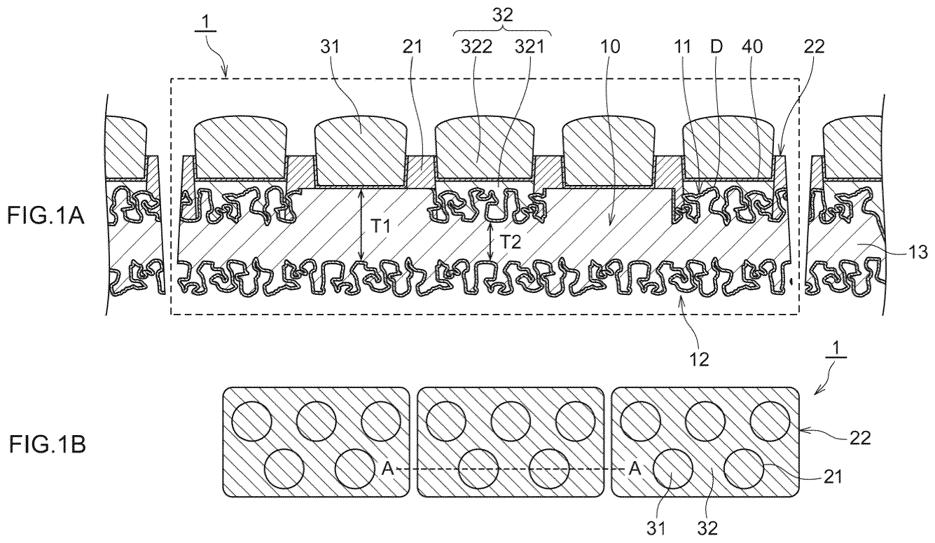

FIG. 1A is a schematic cross-sectional view for explaining the structure of a thin film capacitor 1 according to a first embodiment of the present disclosure. FIG. 1B is a schematic plan view of the thin film capacitor 1. FIG. 1A illustrates a cross section taken along the line A-A in FIG. 1B.

As illustrated in FIGS. 1A and 1B, the thin film capacitor 1 includes a metal foil 10 made of aluminum or the like, ring-shaped or polygonal annular insulating members 21 and 22 formed on an upper surface 11 of the metal foil 10, an electrode layer 31 formed on the upper surface 11 of the metal foil 10 and positioned in a region surrounded by the insulating member 21, and an electrode layer 32 formed on the upper surface 11 of the metal foil and positioned outside the region surrounded by the insulating member 21 but inside a region surrounded by the insulating member 22. The metal foil 10 may be made of copper, chrome, nickel, or tantalum in place of aluminum. The metal foil 10 has upper and lower main surfaces 11 and 12 positioned on the opposite sides. The upper surface 11 of the metal foil 10 is roughened excluding a region where the electrode layer 31 is provided. The lower surface 12 of the metal foil 10 is substantially entirely roughened. A center portion 13 of the metal foil 10 positioned between the upper and lower surfaces 11 and 12 is not roughened. A dielectric film D is formed on the roughened surface of the metal foil 10. When the metal foil 10 is made of aluminum, the dielectric film D may be made of aluminum oxide. The thickness of the non-roughened center portion 13 of the metal foil 10 is T1 in the region where the electrode layer 31 is provided and is T2 in other regions. The thickness T1 is larger than the thickness T2.

The insulating members 21 and 22 are made of, e.g., a resin material. The electrode layer 31 is made of, e.g., a metal material such as copper, nickel, gold, or an alloy material thereof. The electrode layer 31 may have a multilayer structure including a plurality of laminated metal or alloy material layers. The electrode layer 31 is connected to the non-roughened center portion 13 of the metal foil 10 that has the thickness T1. A seed layer 40 may be interposed between the electrode layer 31 and the metal foil 10. In this case, the seed layer 40 serves as a part of the electrode layer 31. The electrode layer 32 includes conductive members 321 and 322. The conductive member 321 is made of, e.g., a conductive polymer. The conductive member 322 is made of the same metal material as the electrode layer 31. The seed layer 40 may be interposed also between the conductive members 321 and 322. In this case, the seed layer 40 serves as a part of the electrode layer 32. The seed layer 40 may be made of a material having a barrier function capable of preventing diffusion of copper or the like constituting the electrode layer 31 and conductive member 322, having high adhesion to the metal foil 10 made of aluminum or the like, insulating members 21 and 22, and the conductive member 321 made of a conductive polymer or the like, and causing no damage to the conductive member 321.

The ring-shaped or polygonal annular insulating member 21 is provided in a slit that electrically separates the electrode layers 31 and 32. In the region surrounded by the insulating member 21, i.e., a region where the non-roughened center portion 13 of the metal foil 10 has the thickness T1, the dielectric film D formed on the upper surface 11 of the metal foil 10 is partially or entirely removed and thus has an opening, whereby the electrode layer 31 is electrically connected to the metal foil 10 through the seed layer 40. On the other hand, outside the region surrounded by the insulating member 21, the dielectric film D formed on the upper surface 11 of the metal foil 10 is not removed. That is, the electrode layer 32 contacts the dielectric film D without contacting the metal foil 10, and the electrode layer 32 and metal foil are insulated from each other. This allows the electrode layers 31 and 32 to function as a pair of capacitive electrodes facing each other through the dielectric film D. The dielectric film D is formed on the roughened upper surface 11 of the metal foil 10, and the upper surface 11 has an increased surface area, whereby a large capacitance can be obtained.

The region where the thickness of the center portion 13 of the metal foil 10 is T1 has a exposed flat surface. The flat surface of the center portion 13 of the metal foil contacts the seed layer 40 and insulating member 21. Since the exposed surface of the center portion 13 is flat, a void hardly occurs between the metal foil 10 and the seed layer 40 and between the metal foil 10 and the insulating member 21. This enhances adhesion of the electrode layer 31 and insulating member 21 to the metal foil 10. In addition, since the non-roughened center portion 13 of the metal foil 10 is larger in thickness portion overlapping the electrode layer 31 than at the other portions, mechanical strength of the entire thin film capacitor 1 is enhanced. The thickness of the metal foil may be substantially unform as a whole. That is, the thickness of the metal foil 10 at a position where the non-roughened center portion 13 is exposed and the thickness thereof at a position having the roughened surface may be substantially the same. In this case, the metal foil 10 is avoided from being locally reduced in thickness at the position overlapping the electrode layer 31, enhancing the entire mechanical strength. In the example illustrated in FIG. 1A, the upper surfaces of the electrode layers 31 and 33 substantially flush with each other, which means that the upper surfaces of the electrode layers 31 and 32 are substantially the same in height position. The height position of the upper surfaces of the electrode layers 31 and 32 is defined with reference to the upper surface 11 of the metal foil 10. When the upper surfaces of the electrode layers 31 and 32 are not flat, the height position thereof is defined by an average height position.

The thin film capacitor 1 can be used as a decoupling capacitor when being embedded in a multilayer substrate. Further, the electrode layer 31 is divided into a plurality of parts, so that ESR and ESL can be reduced as compared with when the number of the electrode layers 31 is one. In addition, in the thin film capacitor 1, the thickness of the center portion 13 of the metal foil 10 is T1 in the region overlapping the electrode layer 31 and T2 (<T1) in other regions, so that when being embedded in a multilayer substrate, the thin film capacitor 1 hardly undergoes rupture of the metal foil 10 due to stress applied through the electrode layer 31. In particular, high stress is likely to be applied to a part of the surface of the metal foil 10 that contacts the edge of the electrode layer 31; however, the metal foil 10 has a sufficient thickness at this part, thus increasing reliability. On the other hand, the roughened surface layer portion of the metal foil 10 and the dielectric film D formed thereon are present, so that when high stress is applied to this portion, a reduction in capacitance or a short-circuit failure may occur; however, in the thin film capacitor 1 according to the present embodiment, the upper surface of the electrode layer 32 does not protrude from the upper surface of the electrode layer 31, making it possible to reduce the stress applied to the roughened surface layer portion of the metal foil 10 and the dielectric film D.

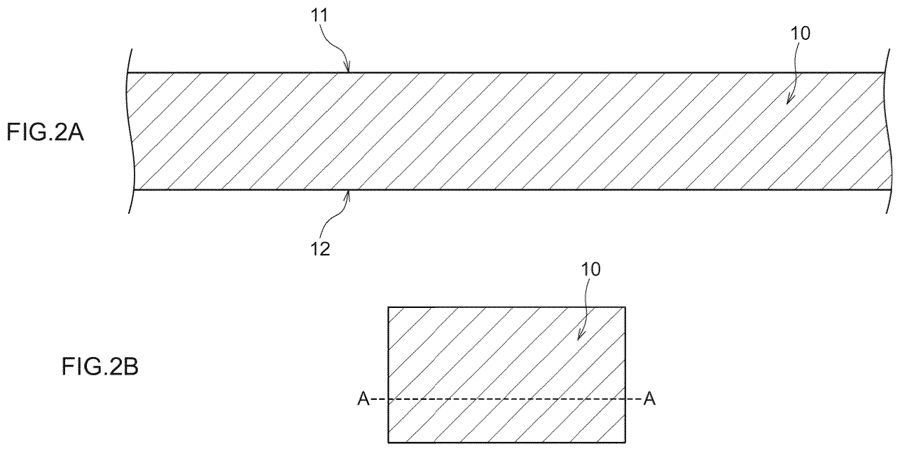

The following describes an example of a manufacturing method for the thin film capacitor 1. FIGS. 2A to 25A are schematic cross-sectional views taken along the line A-A in FIGS. 2B to 25B.

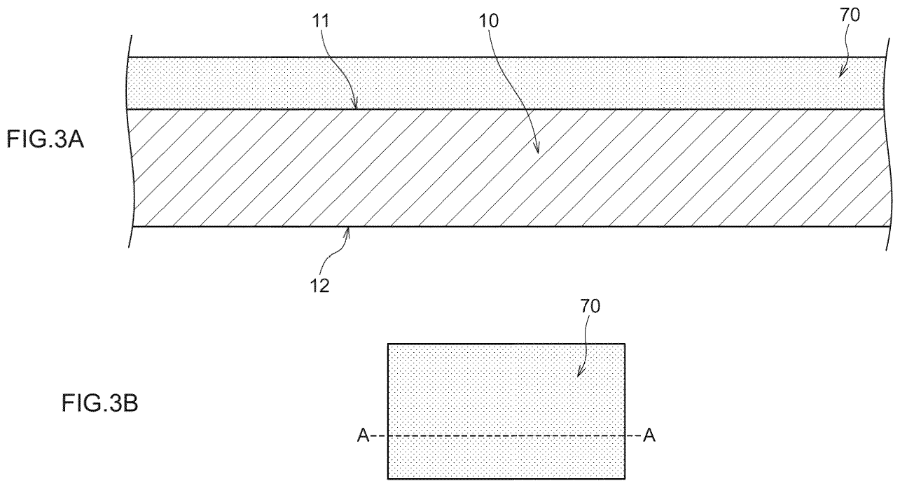

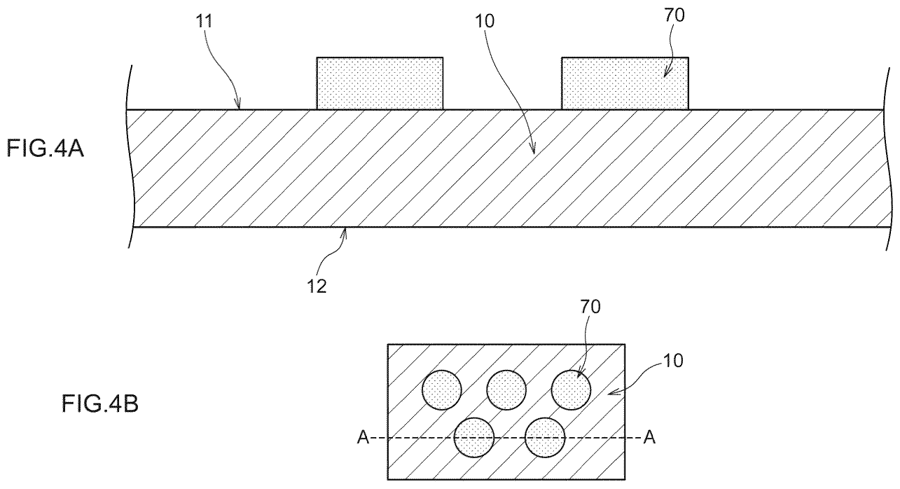

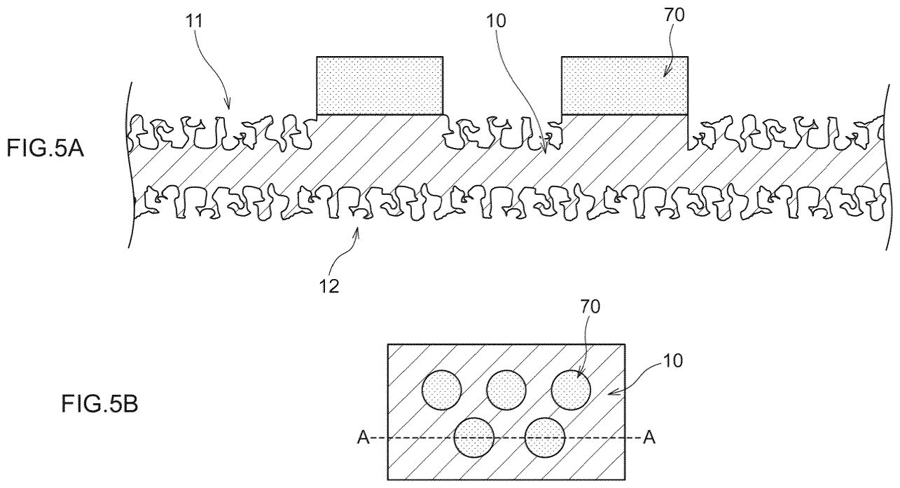

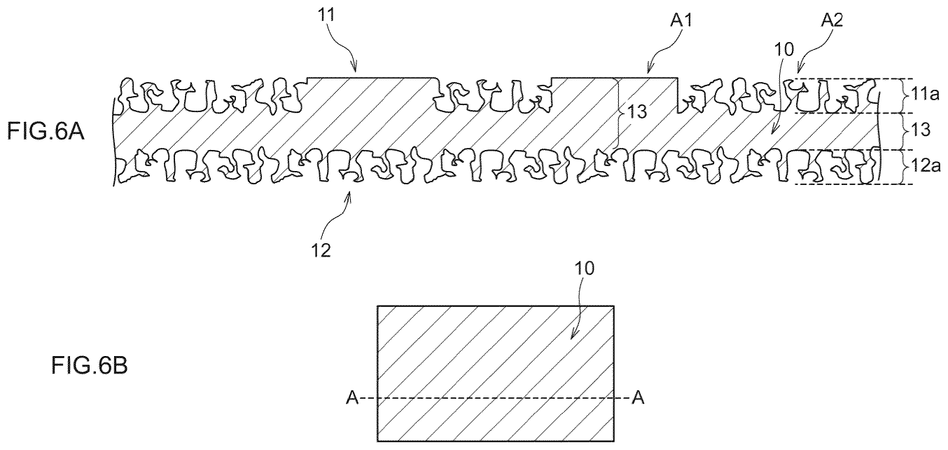

First, the metal foil 10 with a thickness of about 50 μm is prepared (FIGS. 2A and 2B), and a photosensitive liquid resist 70 is applied onto the upper surface 11 of the metal foil 10 (FIGS. 3A and 3B), followed by exposure and development to pattern the resist 70 (FIGS. 4A and 4B). Subsequently, the upper and lower surfaces 11 and 12 of the metal foil 10 are roughened by etching (FIGS. 5A and 5B), followed by removal of the resist 70 (FIGS. 6A and 6B). In the etching, the upper surface 11 of the metal foil 10 in a region A1 covered with the resist 70 is not roughened but kept flat. On the other hand, the upper surface 11 of the metal foil 10 in a region A2 not covered with the resist 70 is roughened. That is, in the region A2 not covered with the resist 70, the non-roughened center portion 13 changes to a porous layer 11a, while in the region A1 covered with the resist 70, the center portion 13 is not roughened but left unchanged. The lower surface 12 of the metal foil 10 entirely changes to a porous layer 12a. Thus, the non-roughed center portion 13 is left between the porous layers 11a and 12a. Such selective etching makes the thickness of the center portion 13 of the metal foil 10 in the region A1 covered with the resist 70 larger than the thickness of the center portion 13 of the metal foil 10 in the region A2 not covered with the resist 70. Here, only necessary is to roughen at least the upper surface 11 and the lower surface 12 need not necessarily be roughened; however, roughening both the upper and lower surfaces 11 and 12 can prevent warpage of the metal foil 10.

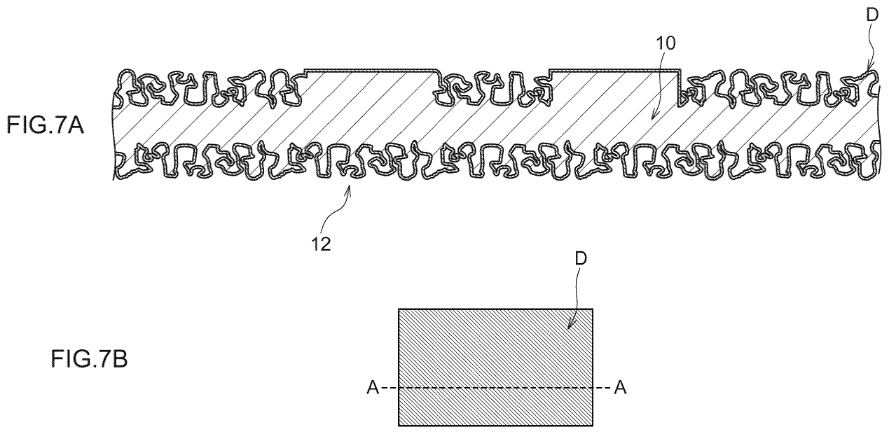

Then, the dielectric film D is formed on the surfaces of the metal foil 10 (FIGS. 7A and 7B). The dielectric film D may be formed through oxidation of the metal foil or using a film formation method excellent in coverage performance, such as an ALD method, a CVD method, or a mist CVD method. As the material of the dielectric film D, Al₂O₃, TiO₂, Ta₂O₅, or SiNₓ may be used. Here, only required is to form the dielectric film D at least on the upper surface 11 and the dielectric film D need not necessarily be formed on the lower surface 12; however, forming the dielectric film D on the lower surface 12 can provide sufficient insulation performance to the lower surface 12.

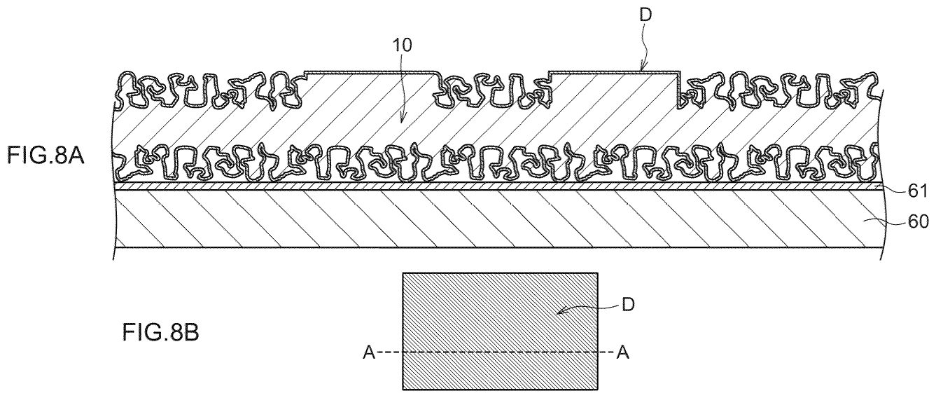

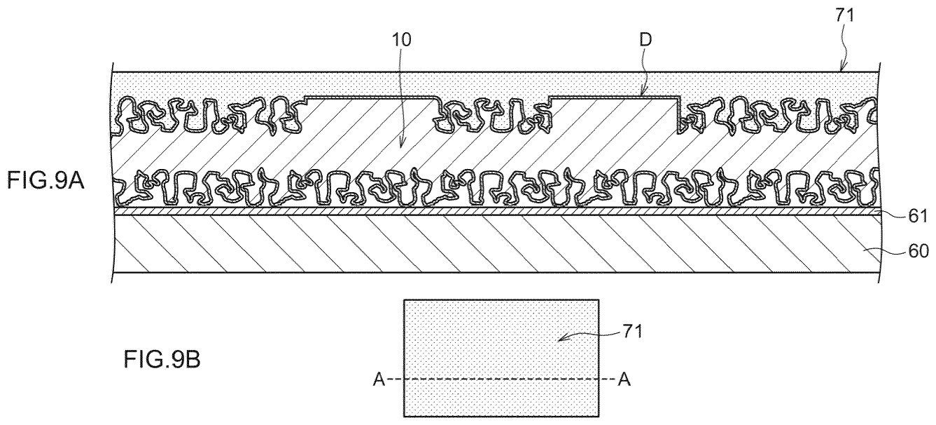

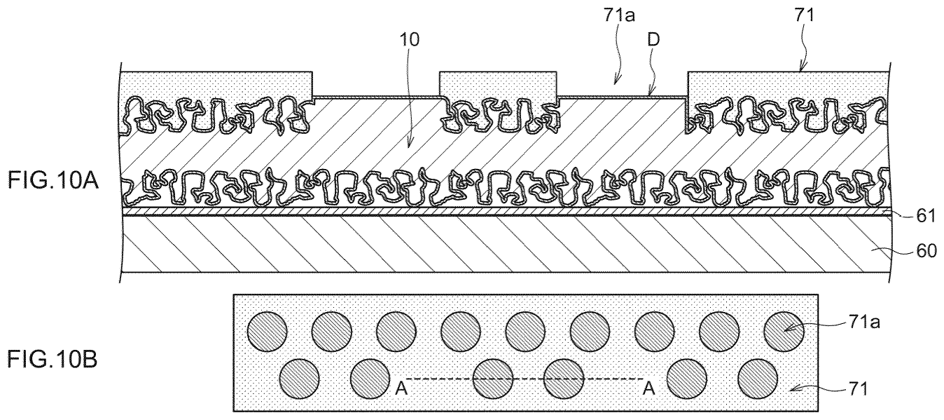

Then, the metal foil 10 is placed on a support substrate 60 with an adhesive layer 61 interposed therebetween (FIGS. 8A and 8B), a photosensitive liquid resist 71 is applied onto the upper surface 11 of the metal foil 10 positioned on the side opposite the support substrate 60 (FIGS. 9A and 9B), followed by exposure and development to pattern the resist 71 (FIGS. 10A and 10B). The resist may be of a positive or negative type. The patterned resist 71 has a plurality of openings 71a exposing the dielectric film D. The openings 71a each overlap the above-described region A1.

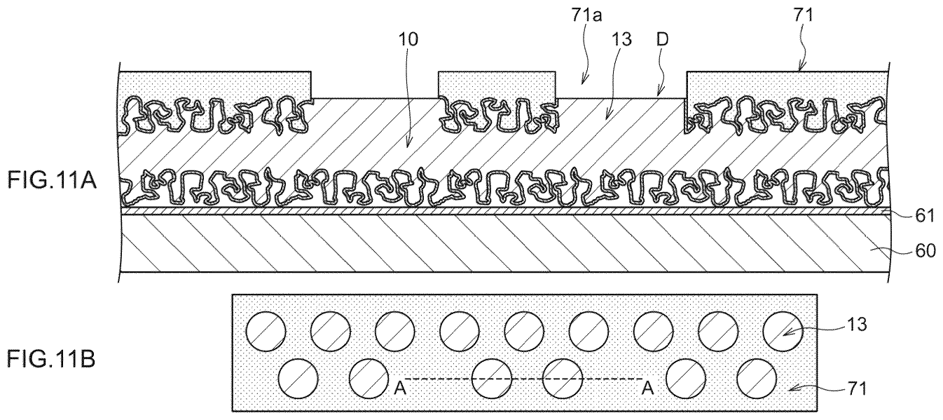

Then, the dielectric film D is etched using the resist 71 as a mask (FIGS. 11A and 11B). As a result, the dielectric film D has openings, through which the non-roughened center portion 13 of the metal foil 10 is exposed.

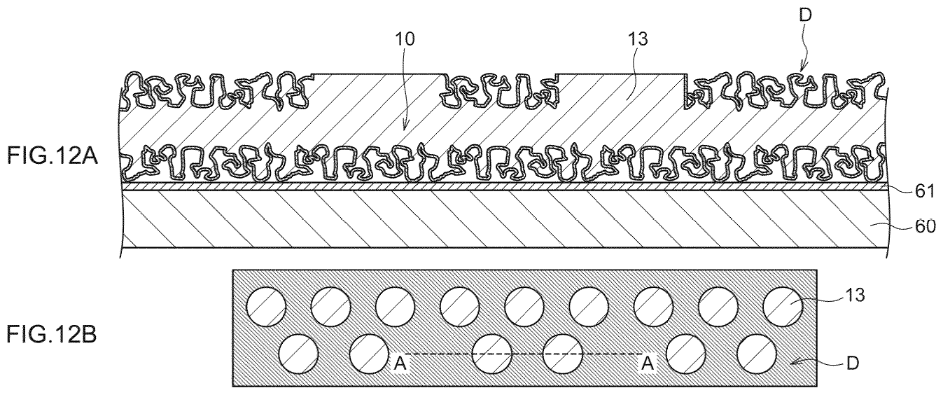

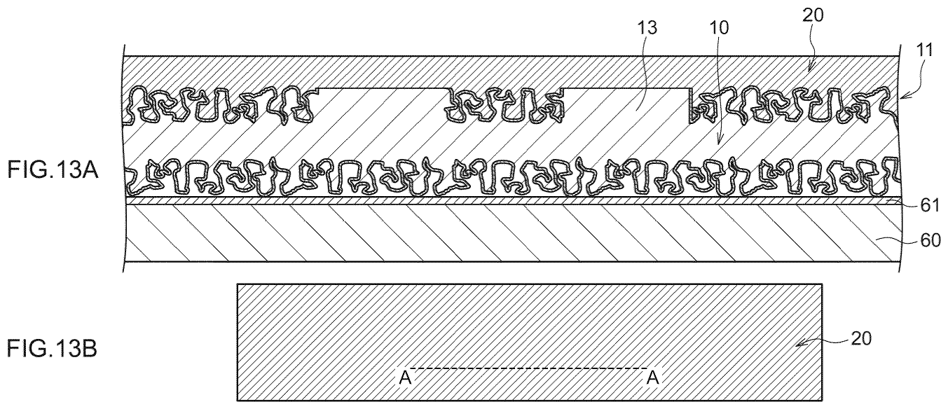

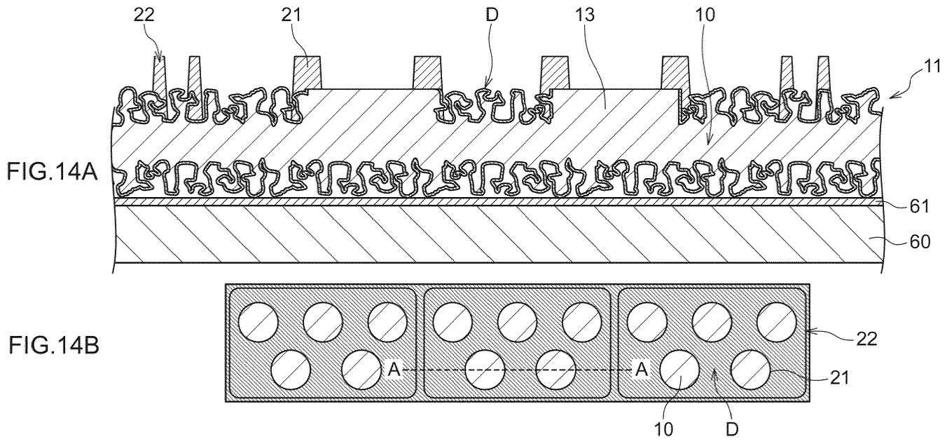

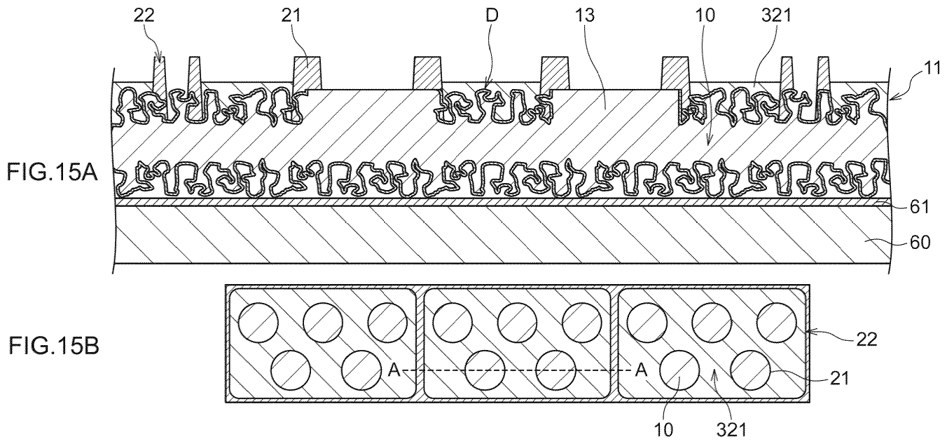

Then, after removal of the resist 71 (FIGS. 12A and 12B), an insulating resin 20 is formed on the upper surface 11 of the metal foil 10 (FIGS. 13A and 13B). Subsequently, a not-shown photosensitive resist is formed on the surface of the insulating resin 20, followed by exposure and development to pattern the insulating resin 20 (FIGS. 14A and 14B). As a result, the ring-shaped insulating members 21 and 22 are formed. The inner peripheral wall of the ring-shaped insulating member 21 may be positioned within the flat exposed surface of the center portion 13. The outer peripheral wall of the ring-shaped insulating member 21 needs to be positioned outside the exposed surface of the center portion 13. Subsequently, the conductive member 321 made of a conductive polymer is formed outside the region surrounded by the insulating member 21 but inside the region surrounded by the insulating member 22 (FIGS. 15A and 15B). The conductive member 321 made of a conductive polymer is not formed in the region surrounded by the insulating member 21 and a portion where the metal foil 10 is to be removed for singulation (for example, a portion outside the region surrounded by the insulating member 22).

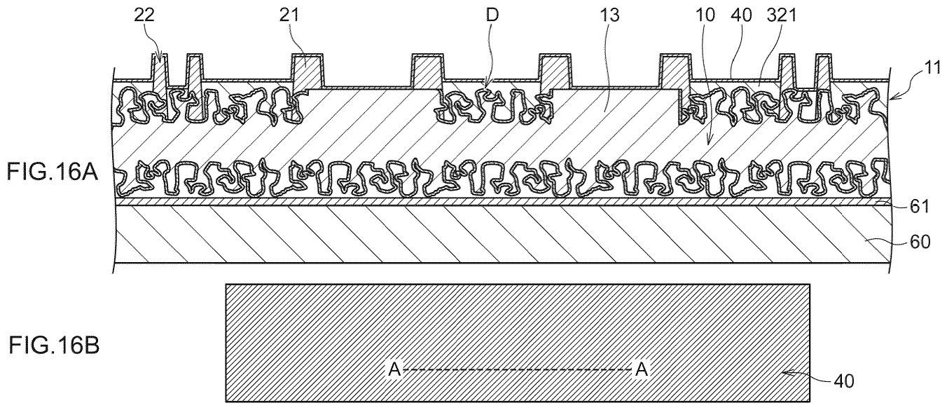

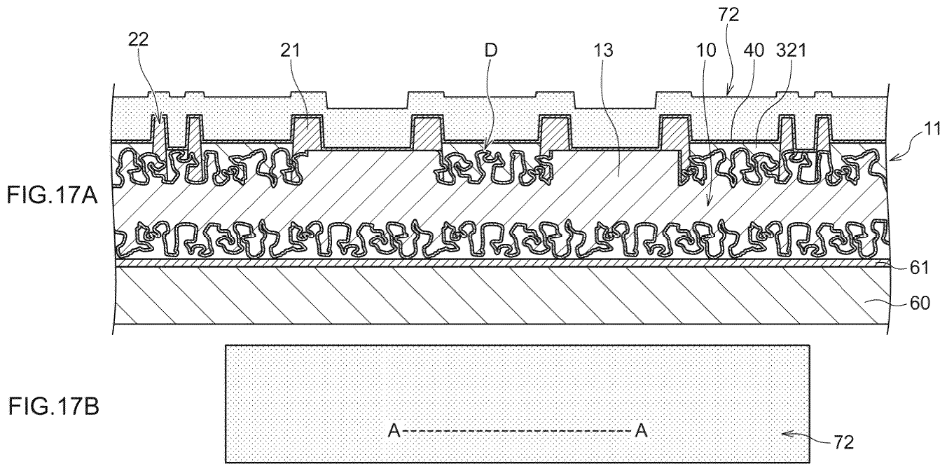

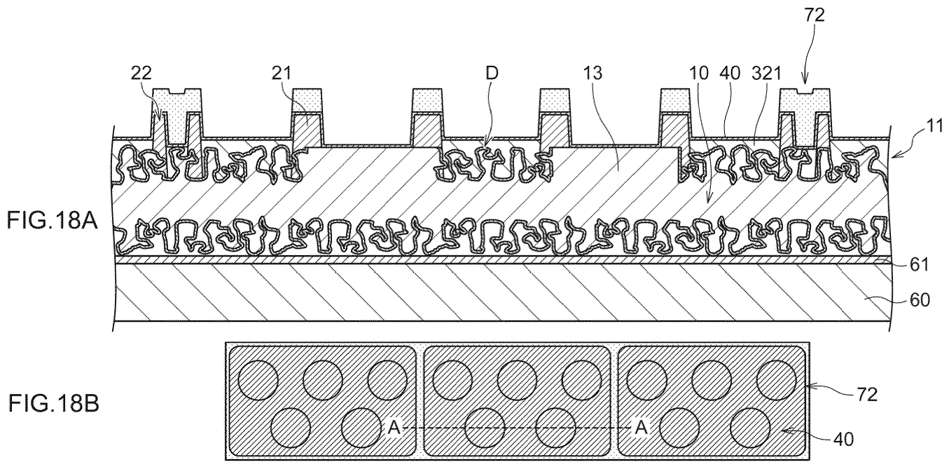

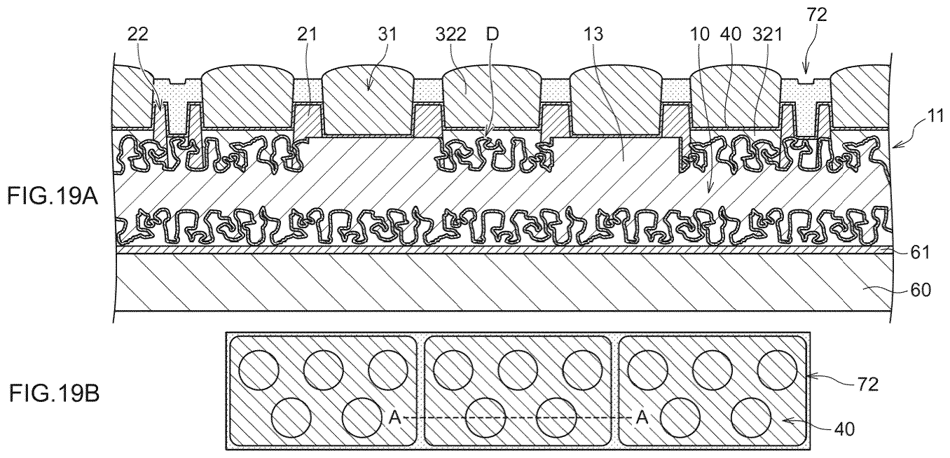

Then, the seed layer 40 is formed on the entire surface using a sputtering method or the like (FIGS. 16A and 16B). Before the seed layer 40 is formed, a residue remaining on the surface may be removed by reverse sputtering. Subsequently, a photosensitive liquid resist 72 is applied onto the entire surface (FIGS. 17A and 17B), followed by exposure and development to pattern the resist 72 (FIGS. 18A and 18B). As a result, the seed layer 40 in the singulation region is exposed. Subsequently, electrolytic plating is performed using the seed layer 40 as a feeding film to form the electrode layer 31 and the conductive member 322 of the electrode layer 32 (FIGS. 19A and 19B). As a result, the electrode layer 31 is connected to the metal foil 10, and the conductive member 322 is connected to the conductive member 321 made of a conductive polymer or the like.

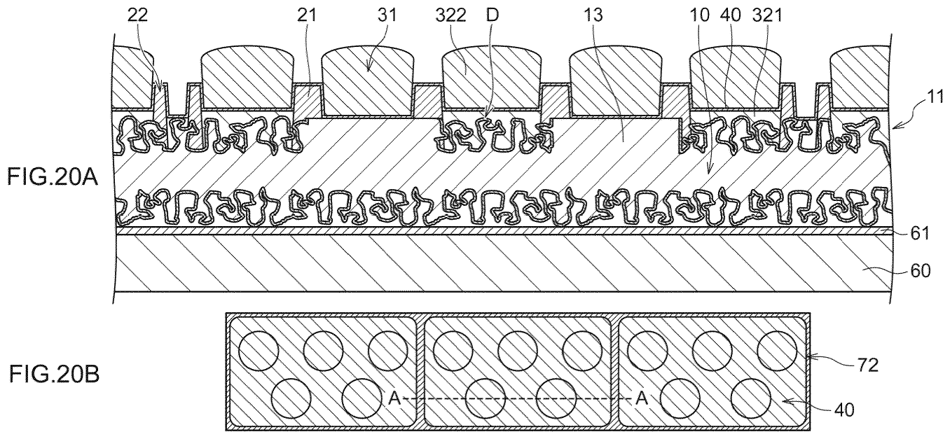

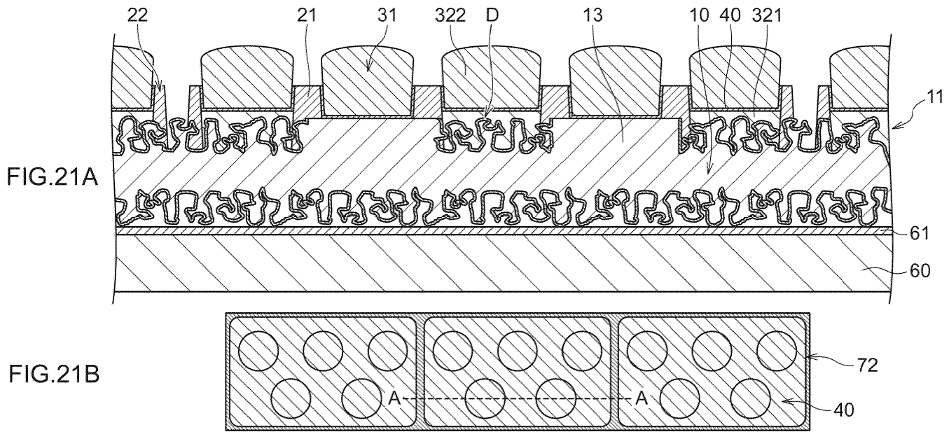

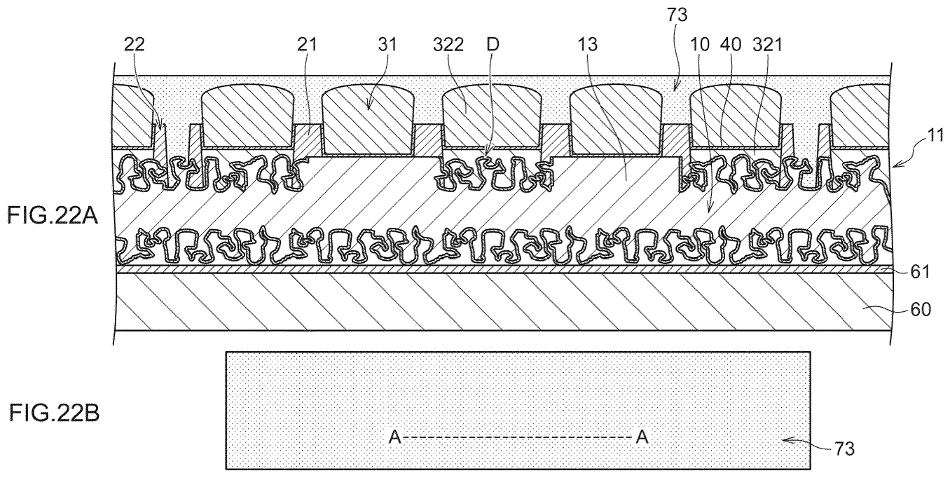

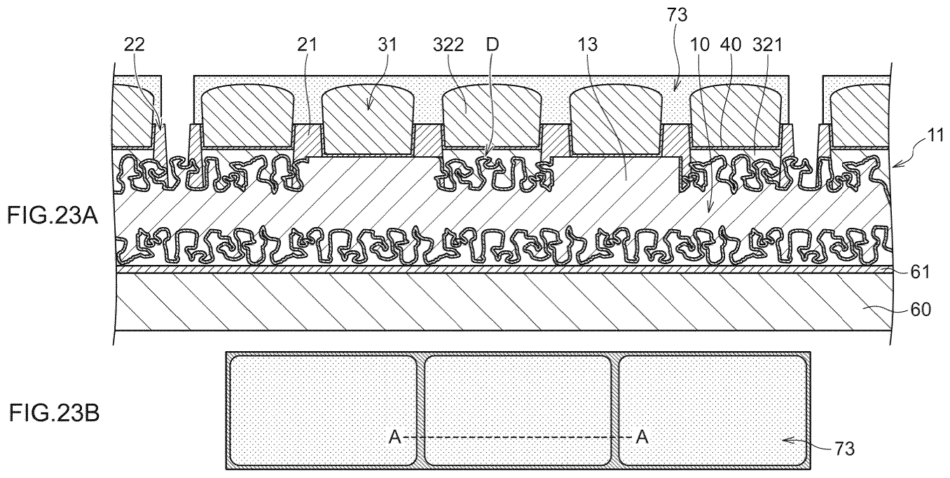

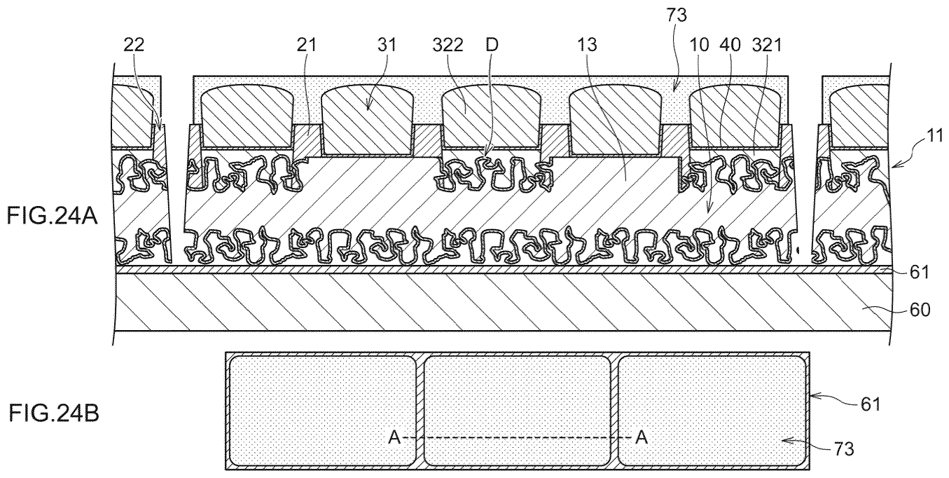

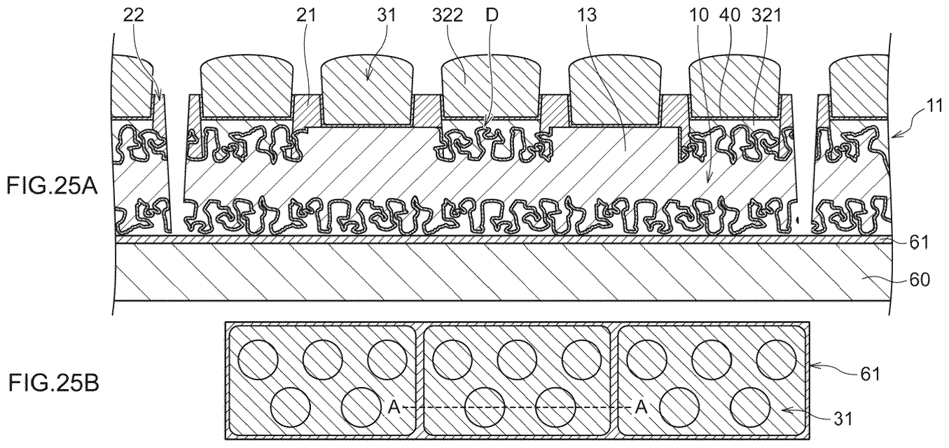

Then, after removing the resist 72 by ashing or the like (FIGS. 20A and 20B), an unnecessary part of the seed layer is removed (FIGS. 21A and 21B). Then, a photosensitive liquid resist 73 is applied onto the entire surface (FIGS. 22A and 22B), followed by exposure and development to pattern the resist 73 (FIGS. 23A and 23B). Subsequently, the metal foil 10 is etched using the resist 73 as a mask to singulate the thin film capacitor (FIGS. 24A and 24B). Subsequently, after removing the resist 73 by ashing or the like (FIGS. 25A and 25B), the support substrate 60 and adhesive layer 61 are removed, whereby the thin film capacitor 1 illustrated in FIGS. 1A and 1B is completed.

As described above, the metal foil 10 is selectively etched in the present embodiment, so that the thickness of the non-roughened center portion 13 of the metal foil 10 can be selectively made large at a position overlapping the electrode layer 31.

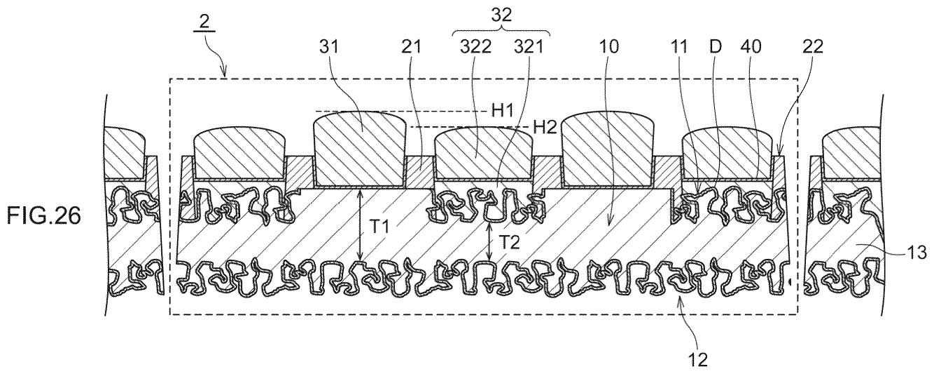

FIG. 26 is a schematic cross-sectional view for explaining the structure of a thin film capacitor 2 according to a second embodiment of the present disclosure.

As illustrated in FIG. 26, in the thin film capacitor 2, an upper surface position H2 of the electrode layer 32 is lower than an upper surface position H1 of the electrode layer 31. The roughened surface layer portion of the metal foil 10 and the dielectric film D formed on the surface thereof are present under the electrode layer 32, so that when high stress is applied to this portion, a reduction in capacitance or a short-circuit failure may occur; however, in the thin film capacitor 2 according to the present embodiment, the electrode layer 32 does not protrude from the electrode layer 31, so that when the thin film capacitor 2 is embedded in a multilayer substrate, stress is less likely to be applied to the electrode layer 32. This makes the capacitance reduction and short-circuit failure less likely to occur.

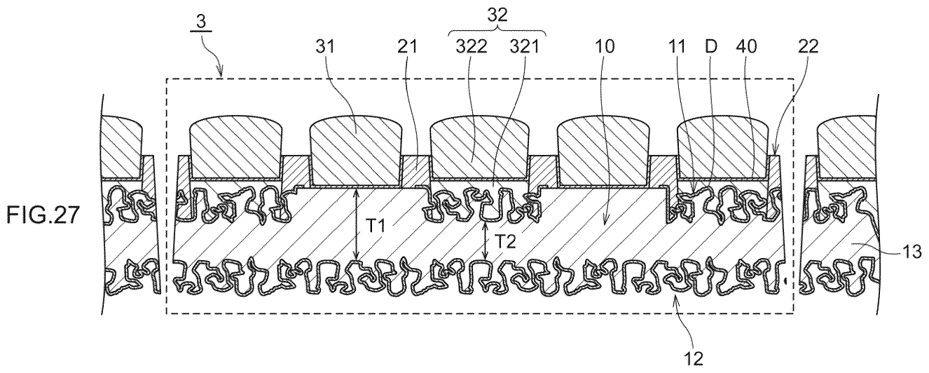

FIG. 27 is a schematic cross-sectional view for explaining the structure of a thin film capacitor 3 according to a third embodiment of the present disclosure.

As illustrated in FIG. 27, in the thin film capacitor 3, the flat surface constituting the upper surface 11 of the metal foil 10 on which the electrode layer 31 is formed is partially covered with the dielectric film D. It is thus not essential that the flat surface constituting the upper surface 11 of the metal foil 10 on which the electrode layer 31 is formed is exposed without being entirely covered with the dielectric film D, and a part of the flat surface may be partially covered with the dielectric film D.

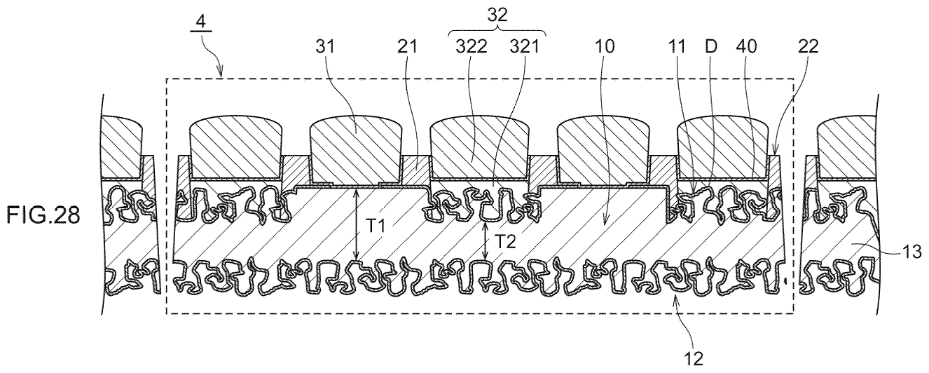

FIG. 28 is a schematic cross-sectional view for explaining the structure of a thin film capacitor 4 according to a fourth embodiment of the present disclosure.

As illustrated in FIG. 28, a part of the upper surface 11 of the metal foil 10 that overlaps the electrode layer 31 is partially covered with the dielectric film D. It is thus not essential that the lower surface of the electrode layer 31 entirely contacts the upper surface 11 of the metal foil 10, and the dielectric film D may be partially interposed therebetween.

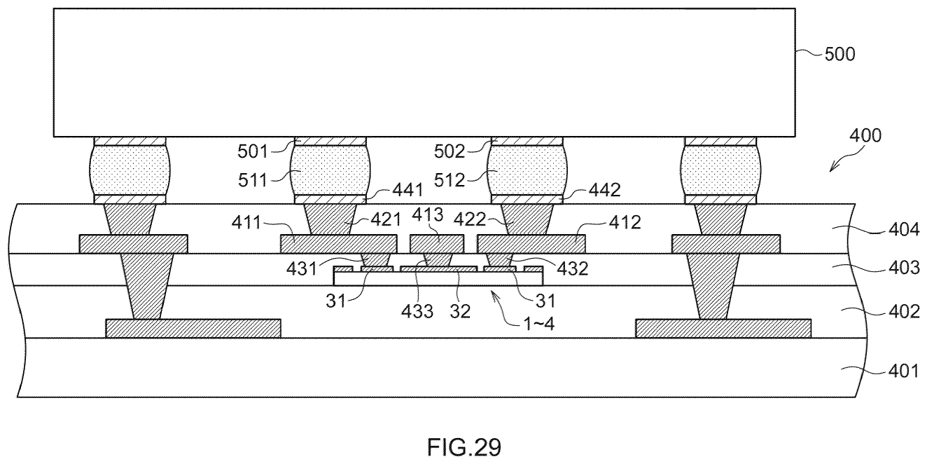

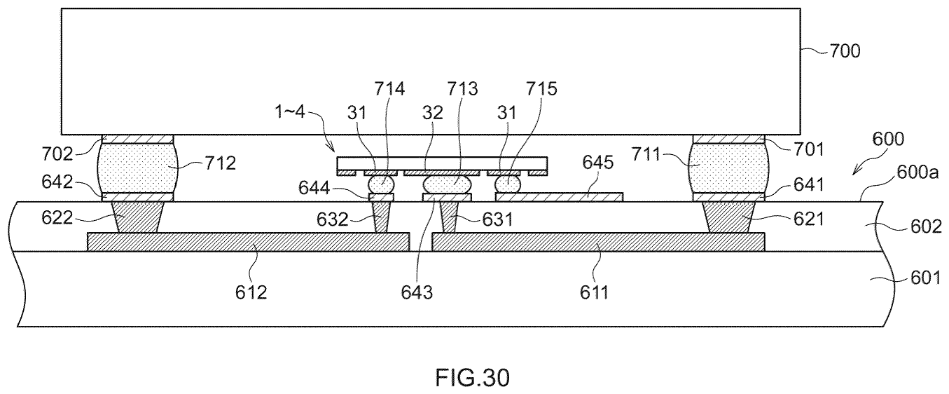

The above-described thin film capacitors 1 to 4 may be embedded in a multilayer substrate 400 as illustrated in FIG. 29 or mounted on the surface of a multilayer substrate 600 as illustrated in FIG. 30.

An electric circuit board illustrated in FIG. 29 has a configuration in which a semiconductor IC 500 is mounted on a multilayer substrate 400. The multilayer substrate 400 includes a plurality of insulating layers including insulating layers 401 to 404 and a plurality of wiring patterns including wiring patterns 411 and 413. The number of the insulating layers is not particularly limited. In the example illustrated in FIG. 29, any one of the thin film capacitors 1 to 4 is embedded between the insulating layers 402 and 403. There are provided on the surface of the multilayer substrate 400 a plurality of land patterns including land patterns 441 and 442. The semiconductor IC 500 has a plurality of pad electrodes including pad electrodes 501 and 502. For example, the pad electrodes 501 and 502 are power supply terminals. The pad electrode 501 and land pattern 441 are connected to each other through a solder 511, and the pad electrode 502 and land pattern 442 are connected to each other through a solder 512. The land pattern 441 is connected to the electrode layer 31 of the thin film capacitor (1 to 4) through a via conductor 421, the wiring pattern 411, and a via conductor 431. The land pattern 442 is connected to another electrode layer 31 of the thin film capacitor (1 to 4) through a via conductor 422, the wiring pattern 412, and a via conductor 432. The electrode layer 32 of the thin film capacitor (1 to 4) is connected to another pad electrode provided on the semiconductor IC 500 through a via conductor 433 and the wiring pattern 413. The another pad electrode is a ground terminal, for example. With this configuration, the thin film capacitors 1 to 4 each function as a decoupling capacitor for the semiconductor IC 500.

An electric circuit substrate illustrated in FIG. 30 has a configuration in which a semiconductor IC 700 is mounted on a multilayer substrate 600. The multilayer substrate 600 includes a plurality of insulating layers including insulating layers 601 and 602 and a plurality of wiring patterns including wiring patterns 611 and 612. The number of the insulating layers is not particularly limited. In the example illustrated in FIG. 30, any one of the thin film capacitors 1 to 4 is surface-mounted on a surface 600a of the multilayer substrate 600. There are provided on the surface 600a of the multilayer substrate 600 a plurality of land patterns including land patterns 641 to 645. The semiconductor IC 700 has a plurality of pad electrodes including pad electrodes 701 and 702. For example, one of the pad electrodes 701 and 702 is a power supply terminal, and the other one thereof is a ground terminal. The pad electrode 701 and land pattern 641 are connected to each other through a solder 711, and the pad electrode 702 and land pattern 642 are connected to each other through a solder 712. The land pattern 641 is connected to the electrode layer 32 of the thin film capacitor (1 to 4) through a via conductor 621, the wiring pattern 611, a via conductor 631, the land pattern 643, and a solder 713. The land pattern 642 is connected to the electrode layer 31 of the thin film capacitor (1 to 4) through a via conductor 622, the wiring pattern 612, a via conductor 632, the land pattern 644, and a solder 714. The land pattern 645 is connected to another electrode layer 31 through a solder 715. With this configuration, the thin film capacitors 1 to 4 each function as a decoupling capacitor for the semiconductor IC 700.

While the preferred embodiment of the present disclosure has been described, the present disclosure is not limited to the above embodiment, and various modifications may be made within the scope of the present disclosure, and all such modifications are included in the present disclosure.

### REFERENCE SIGNS LIST

1-4 thin film capacitor
10 metal foil
11 upper surface of metal foil
12 lower surface of metal foil
11a, 12a porous layer
13 center portion
14 groove
20 insulating resin
21, 22 insulating member
30 metal film
31, 32 electrode layer
40 seed layer
60 support substrate
61 adhesive layer
70-73 resist
71a opening of resist
321, 322 conductive member
400 multilayer substrate
401-404 insulating layer
411-413 wiring pattern
421, 422, 431-433 via conductor
441, 442 land pattern
500 semiconductor IC
501, 502 pad electrode
511, 512 solder
600 multilayer substrate
600a surface of multilayer substrate
601, 602 insulating layer
611, 612 wiring pattern
621, 622, 631, 632 via conductor
641-645 land pattern
700 semiconductor IC
701, 702 pad electrode
711-715 solder
A1, A2 region
D dielectric film

1. A thin film capacitor comprising:
a metal foil having a non-roughened center portion and a roughened surface;
a dielectric film covering the roughened surface of the metal foil;
a first electrode layer contacting the non-roughened center portion of the metal foil through an opening formed in the dielectric film; and
a second electrode layer contacting the dielectric film without contacting the metal foil,
wherein the center portion of the metal foil is larger in thickness at a position overlapping the first electrode layer than at a position overlapping the second electrode layer.

2. The thin film capacitor as claimed in claim 1, wherein an upper surface position of the second electrode layer is a same as or lower than an upper surface position of the first electrode layer.

3. The thin film capacitor as claimed in claim 1, wherein the center portion of the metal foil that contacts the first electrode layer is flat.

4. The thin film capacitor as claimed in claim 3, wherein the flat center portion of the metal foil is partially covered with the dielectric film.

5. The thin film capacitor as claimed in claim 1, wherein the second electrode layer includes a first conductive member contacting the dielectric film and made of a conductive polymer material and a second conductive member contacting the first conductive member and made of a metal material.

6. An electronic circuit board comprising:
a substrate having a wiring pattern; and
a semiconductor IC and the thin film capacitor as claimed in claim 1 each provided in the substrate,
wherein the first and second electrode layers of the thin film capacitor are connected to the semiconductor IC through the wiring pattern.

7. A method of manufacturing a thin film capacitor, the method comprising:
partially roughening a surface of a metal foil to form, on the metal foil surface, a first region where a non-roughened center portion is exposed and a roughened second region;
forming a dielectric film on the second region of the metal foil surface; and
forming a first electrode layer contacting the first region of the metal foil surface and a second electrode layer contacting the dielectric film without contacting the metal foil.

8. The method of manufacturing a thin film capacitor as claimed in claim 7, wherein the partially roughening of the surface of the metal foil includes etching the second region of the metal foil surface with the first region of the metal foil surface covered with a resist.

9. The method of manufacturing a thin film capacitor as claimed in claim 7, wherein the forming the dielectric film includes forming the dielectric film in the first and second regions of the surface of the metal foil and removing the dielectric film formed on the first region.
